(19) United States
(12) Patent Application Publication
(10) Pub. No.: US 2009/0106977 A1
(43) Pub. Date: Apr. 30, 2009

(54) Manufacturing method of printed circuit board

(75) Inventors: Jin-Cheol Kim, Hwaseong-si (KR); Jun-Rok Oh, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/149,836

(22) Filed: May 8, 2008

(30) Foreign Application Priority Data
Oct. 26, 2007 (KR) 10-2007-0108378

(51) Int. Cl. H05K 3/40

(52) U.S. Cl. 29/852; 29/830; 29/846; 29/847; 174/262

(57) ABSTRACT

A manufacturing method of a printed circuit board is disclosed. The method may include: forming a circuit pattern on a surface of an insulation layer, made primarily from a thermoplastic resin, such that the circuit pattern protrudes from the surface of the insulation layer, and burying the circuit pattern in the insulation layer by pressing the circuit pattern.

### CROSS-REFERENCE TO RELATED APPLICATIONS

This application claims the benefit of Korean Patent Application No. 10-2007-0108378 filed with the Korean Intellectual Property Office on Oct. 26, 2007, the disclosure of which is incorporated herein by reference in its entirety.

### BACKGROUND

1. Technical Field

The present invention relates to a manufacturing method of a printed circuit board.

2. Description of the Related Art

The demand is increasing for the printed circuit board, which is a major part in an electronic device. The decreasing in size of electronic devices requires innovations in packaging methods for integrating and increasing the density of integrated circuit (IC) chips and passive components. Among such methods, one of the most advanced is to use a System in Package (SIP), which can be implemented in various forms. Typical examples of a System in Package include Multi-Chip Package (MCP) and Package on Package (PoP) types. A common set of demands in such forms of packaging includes reducing the thickness and improving the reliability of the printed circuit board.

It is possible to reduce the thickness of a printed circuit board by reducing the thicknesses of the components, including, for example, the solder resist, circuit pattern, and insulation layer. However, reducing the thicknesses of a solder resist and an insulation layer is liable to increase the resistance of electrical conductors through which signals may travel. In addition, the reductions in thicknesses may decrease the adhesive strength between the insulation material and the circuit pattern, so that the reliability of the printed circuit board may be lowered. As such, there is a need for a manufacturing method that provides a thin printed circuit board having high reliability.

### SUMMARY

An aspect of the invention is to provide a manufacturing method of a printed circuit board that has a low thickness and high reliability.

Another aspect of the invention provides a manufacturing method of a printed circuit board that includes: forming a circuit pattern on a surface of an insulation layer, made primarily from a thermoplastic resin, such that the circuit pattern protrudes from the surface of the insulation layer, and burying the circuit pattern in the insulation layer by pressing the circuit pattern.

Burying the circuit pattern may further include softening the insulation layer by heating the insulation layer.

The manufacturing method of a printed circuit board may further include hardening the insulation layer by cooling the insulation layer, after burying the circuit pattern.

The manufacturing method of a printed circuit board of may further include, after burying the circuit pattern, forming a penetration hole by perforating the insulation layer, and electrically connecting the circuit patterns formed on a top and bottom surface of the insulation layer by filling conductive paste in the penetration hole.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a manufacturing method of a printed circuit board according to a first embodiment of the present invention.

FIG. 2, FIG. 3, FIG. 4, FIG. 5, and FIG. 6 are cross-sectional views representing a process diagram for a manufacturing method of a printed circuit board according to a first embodiment of the present invention.

### DETAILED DESCRIPTION

The manufacturing method of a printed circuit board according to certain embodiments of the invention will be described below in more detail with reference to the accompanying drawings. Those elements that are the same or are in correspondence are rendered the same reference numeral regardless of the figure number, and redundant explanations are omitted.

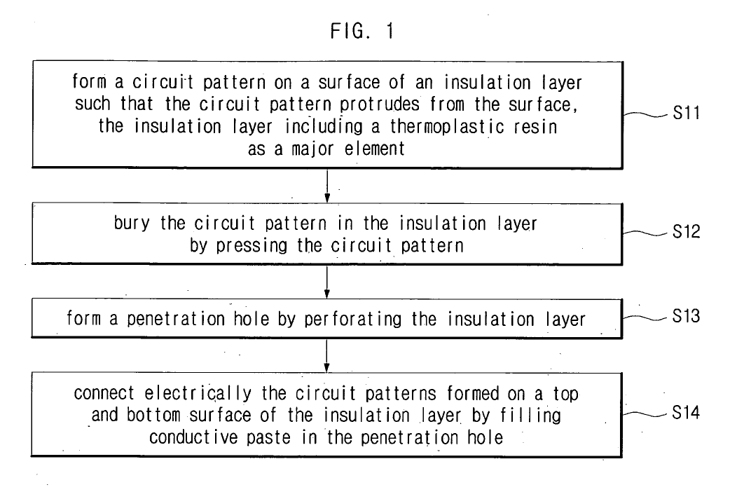

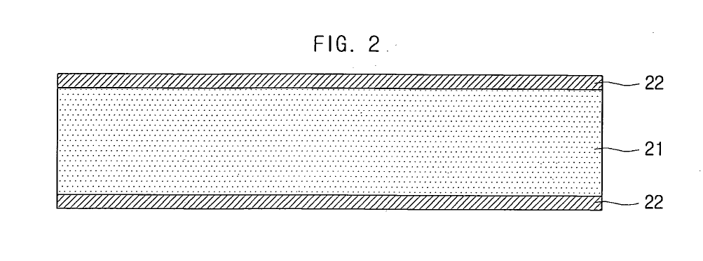

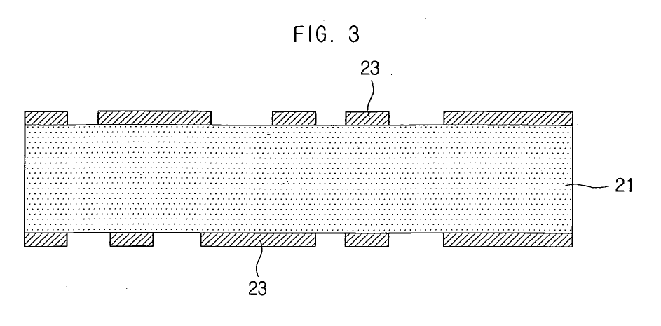

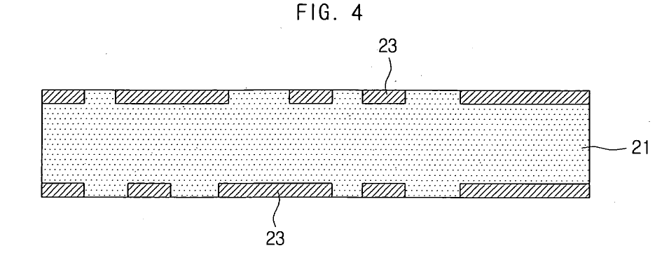

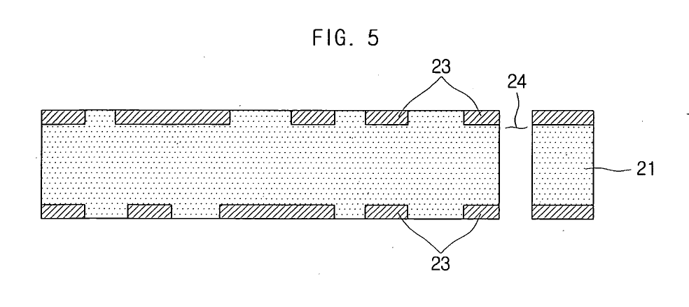

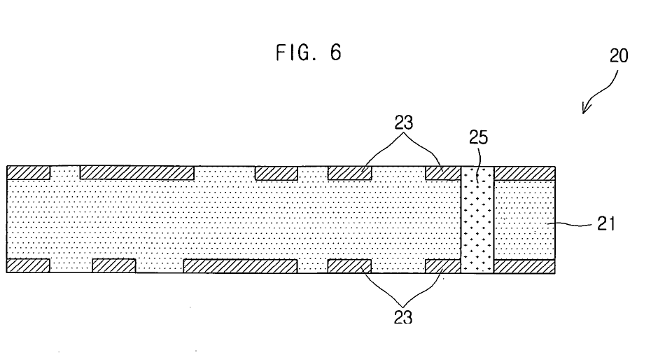

FIG. 1 is a flowchart illustrating a manufacturing method of a printed circuit board according to a first embodiment of the present invention, and FIG. 2 to FIG. 6 are cross-sectional views representing a process diagram for a manufacturing method of a printed circuit board according to a first embodiment of the present invention.

In FIGS. 2 to 6, there are illustrated a printed circuit board 20, an insulation layer 21, metal layers 22, circuit patterns 23, a penetration hole 24, and conductive paste 25.

Operation S11 may include forming circuit patterns 23 on a surface of an insulation layer 21 having a thermoplastic resin base such that the circuit patterns 23 protrude from the surface of the insulation layer 21. FIGS. 2 and 3 represent a corresponding process.

The insulation layer used in a printed circuit board is commonly made of thermosetting resin. In this embodiment, however, an insulation layer 21 may be used which includes thermoplastic resin as a major element. In certain embodiments, the thermoplastic resin can have a melting point of 200 degrees centigrade or higher. Examples of such thermoplastic resins may include Liquid Crystal Polymer (LCP) resins, polytrafluore ethylene (PTEE) resins, etc. The chief ingredient of this insulation layer 21 can be thermoplastic resin, while the insulation layer 21 may further include glass fibers or an inorganic filler. It can be advantageous to have the content of an inorganic filler maintained under 50 percent (%) by volume.

Also, it can be advantageous not to use a thermoplastic resin that has a molecular weight of 100,000 or higher before stacking. This is because it is very difficult for an organic substance having a high molecular weight to flow under high pressure levels.

Various methods can be used for forming the circuit patterns 23 on this insulation layer 21 made of thermoplastic resin. This particular embodiment is illustrated in FIG. 2 and FIG. 3 as employing a subtractive process. The subtractive process may be performed by using a material that has metal layers 22 stacked on both surfaces of the insulation layer 21. The metal layers 22 may commonly be layers of copper. When these metal layers 22 are selectively removed using a photosensitive film and an etchant, the circuit patterns 23 can be formed that protrude from the surface of the insulation layer 21, as in the example shown in FIG. 2.

The circuit pattern 23 may be also formed by semi-additive process besides a method of this embodiment. Because those skilled in the art expect semi-additive process sufficiently, redundant explanations are omitted.

Operation S12 may include burying the circuit patterns 23 in the insulation layer 21 by pressing the circuit patterns 23. The circuit patterns 23 can be buried in the insulation layer 21 using a press, to result in a configuration illustrated in FIG. 4. Here, the thermoplastic resin can be heated such that the thermoplastic resin is softened, whereby the burying may be achieved with greater ease. Thus, the property of the thermoplastic resin can be utilized to bury the circuit patterns 23 in the insulation layer 21 after heating, which can be followed by hardening the insulation layer 21. In this way, operation S12 may be performed with greater ease, while the adhesive strength between the buried circuit patterns 23 and the insulation layer 21 may also be improved.

As the circuit patterns 23 may be buried in the insulation layer 21, the total thickness of the printed circuit board 20 may be decreased, tantamount to the thicknesses of the circuit patterns 23. Moreover, the area of bonding between that the circuit patterns 23 and insulation layer 21 may be increased.

Operation S13 may include forming a penetration hole 24 by perforating the insulation layer 21, where FIG. 5 represents a corresponding process. The penetration hole 24 may be formed using a mechanical drill. Later, the penetration hole 24 can be filled in with conductive paste 25, so that the circuit patterns 23 formed on a top and bottom surface of the insulation layer 21 may be connected electrically.

Operation S14 may include electrically connecting the circuit patterns 23 formed on a top and bottom surface of the insulation layer 21 by filling conductive paste 25 in the penetration hole 23. The conductive paste 25 can be a mixture of conductive metal powder, such as silver (Ag) or copper (Cu), etc., and a binder. By filling the conductive paste 25 in the penetration hole 24, the circuit patterns 23 formed on a top and bottom surface of the insulation layer 21 may be connected electrically without disturbing the arrangement of circuit patterns 23 already buried in the insulation layer 21.

According to certain aspects of the invention as set forth above, thermoplastic resin can be used as an insulation layer, and the circuit patterns can be buried in this insulation layer, whereby a thin film printed circuit board may be manufactured.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
forming a circuit pattern on a surface of an insulation layer such that the circuit pattern protrudes from the surface, the insulation layer including a thermoplastic resin as a major element; and
burying the circuit pattern in the insulation layer by pressing the circuit pattern.

2. The method of claim 1, wherein the burying comprises:
softening the insulation layer by heating the insulation layer.

3. The method of claim 2, further comprising, after the burying:
hardening the insulation layer by cooling the insulation layer.

4. The method of claim 1, further comprising, after the burying:
forming a penetration hole by perforating the insulation layer; and
connecting electrically the circuit patterns formed on a top and bottom surface of the insulation layer by filling conductive paste in the penetration hole.
